(19) United States
(12) Patent Application Publication
(10) Pub. No.: US 2025/0158574 A1
(43) Pub. Date: May 15, 2025

(54) Amplifier With Second Harmonic Termination

(71) Applicant: Ampleon Netherlands B.V., Nijmegen (NL)

(72) Inventor: Dmytro Wolodymyrowytsj Lialiuk, Nijmegen (NL)

(21) Appl. No.: 18/944,777

(22) Filed: Nov. 12, 2024

(30) Foreign Application Priority Data
Nov. 14, 2023 (NL) 2036264

(51) Int. Cl. H03F 1/02; H03F 3/195

(52) U.S. Cl. CPC H03F 1/0288; H03F 3/195; H03F 2200/246; H03F 2200/451

(57) ABSTRACT

The present disclosure relates to an amplifier configured to amplify signals within a given operational frequency, and further relates to an amplifier system, and to a Doherty amplifier. Examples include one or more resonance networks connected to an input terminal of a transistor of the amplifier that each include a first inductor arranged in between the input terminal and an intermediate node, a first capacitor arranged in between the intermediate node and ground, and a series network arranged in between the intermediate node and ground that includes a second inductor and a second capacitor. A susceptance presented by the one or more resonance networks at the input terminal cancels the input susceptance of the transistor at a frequency within an operational frequency band. In addition, an RF short is presented by each resonance network at a second harmonic of which the corresponding fundamental lies within the operational frequency band.

### CROSS-REFERENCE TO RELATED APPLICATION

The present application is a non-provisional patent application claiming priority to Netherlands Patent Application No. NL 2036264, filed Nov. 14, 2023, the contents of which are hereby incorporated by reference.

### FIELD OF THE DISCLOSURE

The present disclosure (e.g., invention) relates to an amplifier configured to amplify signals within a given operational frequency band. The present disclosure (e.g., invention) further relates to an amplifier system, and to a Doherty amplifier that includes (e.g., comprises) such an amplifier or amplifier system.

### BACKGROUND

Recently, Gallium Nitride field-effect transistors, GaN-FETs, have emerged as promising candidates to be used as power transistors in base stations for mobile telecommunications. GaN-FETs offer a high-power density at (e.g., relatively) high frequencies when compared to (e.g., more established) technologies such as laterally diffused metal-oxide-semiconductor, LDMOS, transistors.

It is known in the art that the performance of GaN-FETs depends strongly on the termination at harmonic frequencies. For example, the impedance presented at the gate and drain of GaN-FETs at the second harmonic is of particular importance.

Regarding harmonic termination at the input, it is known to use a double low-pass matching network connected to the gate of the GaN-FET. A double low-pass matching network includes (e.g., comprises) two sections in series, wherein each section includes (e.g., comprises) a series inductor and a shunt capacitor. These matching networks can be tuned such that at the fundamental an impedance match is acquired, while at the second harmonic, a short is presented at the gate of the GaN-FET. The input impedance of a GaN-FET is mostly determined by the gate resistance and the gate-source capacitance.

The bandwidth possible using a double low-pass approach is not always satisfactory.

US 2023/216452 A1 discloses, according to its abstract, an RF amplifier including an amplifier input, a transistor die with a transistor and a transistor input terminal, a fundamental frequency impedance matching circuit coupled between the amplifier input and the transistor input terminal, and a harmonic frequency termination circuit coupled between the transistor input terminal and a ground reference node. The harmonic frequency termination circuit includes a first inductance coupled between the transistor input terminal and a first node, and a tank circuit coupled between the first node and the ground reference node. The tank circuit includes a first capacitance coupled between the first node and the ground reference node, and a second inductance coupled between the first node and the ground reference node. The tank circuit is configured to shunt signal energy at or near a second harmonic frequency, while appearing as an open circuit to signal energy at a fundamental frequency of operation of the RF amplifier.

An object of the present disclosure (e.g., invention) is to provide a (e.g., different) method by which termination at the second harmonic at the input of the GaN-FET can be realized.

### SUMMARY

In a first example implementation, an amplifier (1) configured to amplify signals within a given operational frequency band f₀±BW/2 that has a center frequency f₀ and a bandwidth BW is provided. The amplifier includes a transistor (Q1) having an input terminal, and at least one resonance network (RN; RN1, RN2) arranged in between the input terminal and ground. Each resonance network includes a first inductor (L1) arranged in between the input terminal and an intermediate node (N), a first capacitor (C1) arranged in between the intermediate node and ground, a series network (SN) arranged in between the intermediate node and ground that includes (e.g., comprises) a second inductor (L2) and a second capacitor (C2). A susceptance is presented by the at least one resonance network at the input terminal equals −B_{FET} at a frequency f₁ that lies in the operational frequency band and B_{FET} is the input susceptance of the transistor at the frequency f₁. For the n-th resonance network among the at least one resonance network, the series network displays a series resonance at a frequency that is smaller than f₁, an RF short is presented by the resonance network at the input terminal at a frequency 2×f₂ₙ, wherein the frequency f₂ₙ lies in the operational frequency band, and wherein n represents an integer between 1 and N with N being the total number of resonance networks.

In an example implementation of the amplifier, it may be that 0.8<f₂ₙ/f₁<1.2, more preferably 0.9<f₂ₙ/f₁<1.1.

In an example implementation of the amplifier, each resonance network is designed such that at a respective frequency f₃ₙ, the series network is inductive and resonates with the first capacitor, wherein 2×f₂ₙ>f₃ₙ>f₁.

In an example implementation, the amplifier may include at least one biasing network (BN) for providing a biasing voltage to the input terminal of the transistor, wherein each respective biasing network is connected to a node in between the second inductor and the second capacitor of a respective resonance network.

In an example implementation, the amplifier may include a driver transistor (Q2) of which an output is connected to the input terminal of the transistor through an impedance matching network (2).

In an example implementation, the amplifier may include a substrate (10), a semiconductor die (11) on which the transistor is integrated, wherein the transistor includes (e.g., comprises) a first bond assembly that is electrically connected to the input terminal of the transistor, and wherein the first inductor of each resonance network is at least partially formed by one or more bondwires that are physically connected to the first bond assembly.

In an example implementation, the amplifier may include a further die on which at least the first capacitor of each resonance network is arranged, wherein a first terminal of the first capacitor is electrically connected to a second bond assembly that is arranged on the further die, wherein another end of the one or more bondwires is physically connected to the second bond assembly, and wherein a second terminal of the first capacitor is configured to be grounded during operation.

In an example implementation of the amplifier, the first capacitor is a metal-insulator-metal capacitor integrated on the further die.

In an example implementation of the amplifier, the further die is a semiconductor die, such as a Silicon die.

In an example implementation of the amplifier, the second inductor is integrated on the further die, wherein a first end of the second inductor is connected to the first terminal of the first capacitor.

In an example implementation of the amplifier, the second capacitor is integrated on the further die, wherein a first terminal of the second capacitor is connected to a second end of the second inductor, and wherein a second terminal of the second capacitor is configured to be grounded during operation.

In an example implementation of the amplifier, the second capacitor is a high-density capacitor, such as a deep trench capacitor.

In an example implementation of the amplifier, the further die is mounted on a die pad arranged on the substrate, wherein the die pad is configured to be electrically grounded during operation, wherein the further die has a conductive substrate and/or (e.g., or) a substrate that is provided with vias, wherein a second terminal of the first capacitor and/or (e.g., or) a second terminal of the second capacitor is configured to be grounded during operation through the conductive substrate or through the vias in the substrate.

In an example implementation, the amplifier includes a driver transistor (Q2) of which an output is connected to the input terminal of the transistor through an impedance matching network (2), wherein the impedance matching network is at least partially arranged on the further die.

In an example implementation of the amplifier, the transistor is a Gallium Nitride-based field-effect transistor, GaN FET, and wherein the input terminal of the transistor is a gate of the GaN FET.

In an example implementation of the amplifier, f₀ lies in a range between 0.9 and 6.0 GHz, and wherein BW/f₀ lies in a range between 0.01 and 0.15.

In a second example implementation (e.g., embodiment), an amplifier system comprising a first amplifier and a second amplifier, wherein both the first amplifier and the second amplifier include an amplifier (1) configured to amplify signals within a given operational frequency band f₀±BW/2 that has a center frequency f₀ and a bandwidth BW is provided. The amplifier includes a transistor (Q1) having an input terminal, and at least one resonance network (RN; RN1, RN2) arranged in between the input terminal and ground. Each resonance network includes a first inductor (L1) arranged in between the input terminal and an intermediate node (N), a first capacitor (C1) arranged in between the intermediate node and ground, a series network (SN) arranged in between the intermediate node and ground that includes (e.g., comprises) a second inductor (L2) and a second capacitor (C2). A susceptance is presented by the at least one resonance network at the input terminal equals −B_{FET} at a frequency f₁ that lies in the operational frequency band and B_{FET} is the input susceptance of the transistor at the frequency f₁. For the n-th resonance network among the at least one resonance network, the series network displays a series resonance at a frequency that is smaller than f₁, an RF short is presented by the resonance network at the input terminal at a frequency 2×f₂ₙ, wherein the frequency f₂ₙ lies in the operational frequency band, and wherein n represents an integer between 1 and N with N being the total number of resonance networks. The output terminals of the transistors of the first and second amplifiers are mutually shorted, and wherein the input terminals of the transistors of the first and second amplifiers are electrically connected to each other through a resistive connection.

In an example implementation, the amplifier of the first amplifier and the amplifier of the second amplifier each include a substrate (10) and a semiconductor die (11) on which the transistor is integrated, wherein the transistor includes (e.g., comprises) a first bond assembly that is electrically connected to the input terminal of the transistor. The first inductor of each resonance network is at least partially formed by one or more bondwires that are physically connected to the first bond assembly. The transistor of the first amplifier and the transistor of the second amplifier are arranged on the same semiconductor die. The transistor of the first amplifier includes (e.g., comprises) a first plurality of input fingers that is connected to the first bond assembly of the first amplifier. The transistor of the second amplifier includes (e.g., comprises) a second plurality of input fingers that is connected to the first bond assembly of the second amplifier. The first bond assemblies of the first and second amplifiers are mutually electrically connected through the resistive connection.

In an example implementation, the amplifier of the first amplifier and the amplifier of the second amplifier each further include a driver transistor (Q2) of which an output is connected to the input terminal of the transistor through an impedance matching network (2), a further die on which at least the first capacitor of each resonance network is arranged, wherein a first terminal of the first capacitor is electrically connected to a second bond assembly that is arranged on the further die, wherein another end of the one or more bondwires is physically connected to the second bond assembly, and wherein a second terminal of the first capacitor is configured to be grounded during operation. The first amplifier and the second amplifier use the same further die. The impedance matching network for the first amplifier includes a first matching capacitor arranged on the further die having a non-grounded terminal and a grounded terminal, and one or more bondwires extending between the non-grounded terminal of the first matching capacitor and the first bond assembly of the first amplifier. The impedance matching network for the second amplifier includes a second matching capacitor arranged on the further die having a non-grounded terminal and a grounded terminal, and one or more bondwires extending between the non-grounded terminal of the second matching capacitor and the first bond assembly of the second amplifier. The first and second matching capacitors are combined into a single matching capacitor, wherein the single matching capacitor is arranged in between the first capacitors of the first and second amplifiers.

In a third example implementation (e.g., embodiment), a Doherty amplifier is provided. The Doherty amplifier including a Doherty splitter configured for splitting a signal to be amplified into a main signal and a peak signal, a main amplifier configured to amplify the main signal, a peak amplifier configured to amplify the peak signal, and a Doherty combiner for combining the amplified main signal and the amplified peak signal, wherein at least one of the main amplifier and peak amplifier include (e.g., comprise) the amplifier (1) configured to amplify signals within a given operational frequency band f₀±BW/2 that has a center frequency f₀ and a bandwidth BW is provided. The amplifier includes a transistor (Q1) having an input terminal, and at least one resonance network (RN; RN1, RN2) arranged in between the input terminal and ground. Each resonance network includes a first inductor (L1) arranged in between the input terminal and an intermediate node (N), a first capacitor (C1) arranged in between the intermediate node and ground, a series network (SN) arranged in between the intermediate node and ground that includes (e.g., comprises) a second inductor (L2) and a second capacitor (C2). A susceptance is presented by the at least one resonance network at the input terminal equals −B_{FET} at a frequency f₁ that lies in the operational frequency band and B_{FET} is the input susceptance of the transistor at the frequency f₁. For the n-th resonance network among the at least one resonance network, the series network displays a series resonance at a frequency that is smaller than f₁, an RF short is presented by the resonance network at the input terminal at a frequency 2×f₂ₙ, wherein the frequency f₂ₙ lies in the operational frequency band, and wherein n represents an integer between 1 and N with N being the total number of resonance networks.

### BRIEF DESCRIPTION OF THE FIGURES

The above, as well as additional, features will be better understood through the following illustrative and non-limiting detailed description of example implementations (e.g., embodiments), with reference to the appended drawings.

FIG. 1 illustrates a general concept of the present disclosure (e.g., invention);

FIG. 2 illustrates electrical characteristics corresponding to FIG. 1;

FIG. 3 illustrate an implementation (e.g., embodiment) of an amplifier system in accordance with the present disclosure (e.g., invention); and

FIG. 4 illustrates a practical implementation of the implementation (e.g., embodiment) of FIG. 3.

All the figures are schematic, not necessarily to scale, and generally only show parts which are necessary to elucidate example implementations (e.g., embodiments), wherein other parts may be omitted or merely suggested.

### DETAILED DESCRIPTION

Example implementations (e.g., embodiments) will now be described more fully hereinafter with reference to the accompanying drawings. That which is encompassed by the claims may, however, be embodied in many different forms and should not be construed as limited to the implementations (e.g., embodiments) set forth herein; rather, these implementations (e.g., embodiments) are provided by way of example. Furthermore, like numbers refer to the same or similar elements or components throughout. An object of the present invention is to provide a (e.g., different) method by which termination at the second harmonic at the input of the GaN-FET can be realized. It is noted that the present disclosure (e.g., invention) is not limited to GaN-FETs. The concepts of the present invention can be used for transistors or amplifiers in general.

According to the present disclosure (e.g., invention), the abovementioned object can be realized using the amplifier (e.g., as defined in claim 1), which is configured to amplify signals within a given operational frequency band f₀±BW/2. Here, frequency f₀ refers to a center frequency in the operational frequency band, and BW refers to the bandwidth. For example, f₀ may lie in a range between 0.9 and 6.0 GHz, and BW/f₀ may lie in a range between 0.01 and 0.15.

The amplifier according to the present disclosure (e.g., invention) includes (e.g., comprises) a transistor having an input terminal, and at least one resonance network arranged in between the input terminal and ground. Each resonance network includes (e.g., comprises) a first inductor arranged in between the input terminal of the transistor and an intermediate node, a first capacitor arranged in between the intermediate node and ground, and a series network arranged in between the intermediate node and ground. In turn, the series network includes (e.g., comprises) a second inductor and a second capacitor.

A susceptance presented by the at least one resonance network at the input terminal equals −B_{FET} at a frequency f₁ that lies in the operational frequency band, wherein B_{FET} is the input susceptance of the transistor at the frequency f₁. Furthermore, for the n-th resonance network among the at least one resonance network, the series network displays a series resonance at a frequency that is smaller than f₁. In addition, for the n-th resonance network, an RF short is presented by the resonance network at the input terminal at a frequency 2×f₂ₙ, wherein the frequency f₂ₙ lies in the operational frequency band.

In the above, n represents an integer between 1 and N with N being the total number of resonance networks.

According to the present disclosure (e.g., invention), each resonance network presents its own RF short at the input terminal of the transistor at a respective second harmonic, whereas the resonance networks combined cancel the input susceptance of the transistor. For example, a first resonance network may present an RF short at 7.0 GHz, and a susceptance equal to

$$\frac{- 1}{3} {B}_{FET}$$

at 3.6 GHz, whereas a second resonance network may present an RF short at 7.4 GHz, and a susceptance equal to

$$\frac{- 2}{3} {B}_{FET}$$

at 3.6 GHz, wherein B_{FET} is the input susceptance of a GaN-FET at 3.6 GHz. This combination of resonance networks would compensate the gate-source capacitance of the GaN-FET at 3.6 GHz, while also presenting an RF short at 7.0 and 7.4 GHz.

With the amplifier of the present disclosure (e.g., invention), impedance matching at the input of the transistor may be (e.g., greatly) simplified. More specifically, the target impedance of an impedance matching network is real instead of complex due to the cancellation of the susceptance. The bandwidth for impedance matching is therefore not or at least to a lesser extent connected to the bandwidth for harmonic termination.

In some implementations (e.g., embodiments), 0.8<f₂ₙ/f₁<1.2, preferably 0.9<f₂ₙ/f₁<1.1, and more preferably 0.95<f₂ₙ/f₁<1.05. In some implementations (e.g., embodiments), f₂ₙ=f₁. Additionally, or alternatively, each resonance network is designed such that at a respective frequency f₃ₙ, the series network is inductive and resonates with the first capacitor, wherein 2×f₂ₙ>f₃ₙ>f₁.

In some implementations (e.g., embodiments), 0.8<f₀/f₁<1.2, preferably 0.9<f₀/f₁<1.1, and more preferably 0.95<f₀/f₁<1.05. In some implementations (e.g., embodiments), f₀=f₁.

The amplifier may include (e.g., comprise) at least one biasing network for providing a biasing voltage to the input terminal of the transistor, wherein each respective biasing network is connected to a node in between the second inductor and the second capacitor of a respective resonance network. The amplifier may additionally or alternatively include (e.g., comprise) a driver transistor of which an output is connected to an input terminal of the corresponding transistor through an impedance matching network.

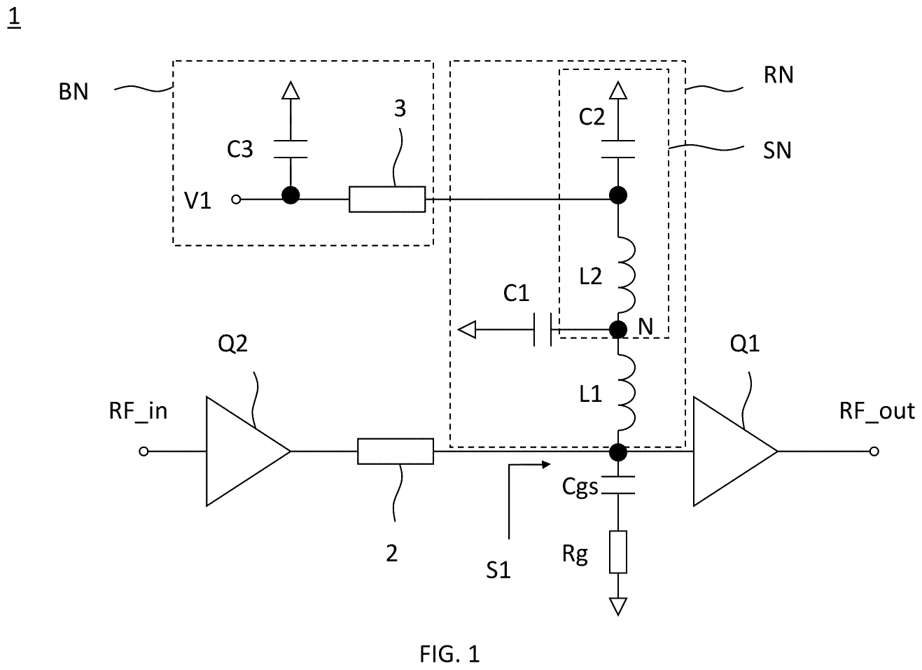

The general concept of the present disclosure (e.g., invention) is illustrated in FIG. 1, wherein amplifier 1 includes (e.g., comprises) a transistor Q1. A driver transistor Q2 is used that drives transistor Q1 through an impedance matching network 2. Transistor Q1 could for example be a GaN-based FET. Amplifier 1 is configured to operate within a given operational frequency band f₀±BW/2. Here, f₀=3.6 GHz, and BW equals 0.4 GHz.

In FIG. 1, the impedance behavior of transistor Q1 at its input terminal is represented by an input capacitance Cgs that is in series with an input resistance Rg. The input admittance Y of Q1 can be written as a sum of an input conductance G and an input susceptance B:

$$Y = G + jB = \frac{j ω Cgs}{j ω CgsRg + 1} = \frac{j ω Cgs}{{( ω CgsRg )}^{2} + 1} + \frac{{ω}^{2} {Cgs}^{2} Rg}{{( ω CgsRg )}^{2} + 1} \qquad Equation 1$$

which for ωCgsRg<<1 reduces to

$$Y = G + jB \approx j ω Cgs + {ω}^{2} {Cgs}^{2} Rg \qquad Equation 2$$

Hereinafter, the input susceptance at frequency f₁ may (e.g., will) be referred to as B_{FET}.

A single resonance network RN is arranged in between the input terminal of Q1 and ground. Resonance network RN includes (e.g., comprises) an inductor L1 arranged in between the input terminal of Q1 and an intermediate node N, a first capacitor C1 arranged in between intermediate node N and ground, and a series network SN arranged in between intermediate node N and ground. Series network SN includes (e.g., comprises) a second inductor L2 and a second capacitor C2.

Hereinafter, component names, such as L1 and C1, may (e.g., will) also be used to indicate the relevant electrical parameter such as inductance L1 and capacitance C1, respectively.

Series network SN displays a series resonance at a frequency fᵣₑₛ which is given by:

$$2 π {f}_{res} = 1 / \sqrt{L 2 C 2} \qquad Equation 3$$

Amplifier 1 is designed such that fᵣₑₛ<f₁. For example, fᵣₑₛ<0.1×f₁. Consequently, for frequencies in the operational frequency band, series network SN is inductive. More specifically, the effective inductance L2* of series network SN within the operational frequency band can be computed from:

$$L {2}^{*} = L 2 ( 1 - {[ \frac{{f}_{res}}{f} ]}^{2} ) \qquad Equation 4$$

Series network SN may (e.g., will) display a parallel resonance with capacitor C1 at a frequency f₃ that is given by:

$$2 π {f}_{3} = 1 / \sqrt{L 2 * C 1} \qquad Equation 5$$

Amplifier 1 is designed such that the combination of series network SN and capacitor C1 may (e.g., will) be inductive for frequencies in or close to the operational frequency band. The effective inductance Leff of this combination may (e.g., will) for such frequencies equal:

$$Leff ( f ) = \frac{L {2}^{*}}{1 - {( \frac{f}{{f}_{3}} )}^{2}} \qquad Equation 6$$

For frequencies f₃>f>fᵣₑₛ, the total inductance Ltot of resonance network RN therefore equals:

$$Ltot ( f ) = Leff ( f ) + L 1 \qquad Equation 7$$

Resonance network RN is designed such that at frequency f₁, the susceptance associated with total inductance Ltot(f₁) equals the inverse of the effective input susceptance of Q1, e.g., −B_{FET}. For ωCgRg<<1, this yields:

$$\frac{1}{2 π {f}_{1} Ltot ( {f}_{1} )} = 2 π {f}_{1} Cgs \qquad Equation 8$$

from which Ltot(f₁) can be calculated using:

$$Ltot ( {f}_{1} ) = \frac{1}{{( 2 π {f}_{1} )}^{2} Cgs} \qquad Equation 9$$

According to the present disclosure (e.g., invention), resonance network RN is designed such that a frequency 2×f₂, an RF short is presented at the input terminal of Q1. This is realized if Leff(2f₂)=−L1:

$$Leff ( 2 {f}_{2} ) = \frac{L {2}^{*} ( 2 {f}_{2} )}{1 - {( \frac{2 {f}_{2}}{{f}_{3}} )}^{2}} = - L 1 \qquad Equation 10$$

which assuming that fᵣₑₛ<<2f₂ reduces to:

$$L 2 = ( {( \frac{2 {f}_{2}}{{f}_{3}} )}^{2} - 1 ) L 1 \qquad Equation 11$$

Accordingly, using resonance network RN configured as described above, it is possible to A) eliminate or alleviate the negative impact of Cgs in the operational frequency band, and B) to present an RF short at second harmonic frequencies.

FIG. 1 also illustrates a biasing network BN that is connected to a node between capacitor C2 and inductor L2. More specifically, capacitor C2 has a grounded terminal and a non-grounded terminal, wherein the biasing network BN is connected to the non-grounded terminal.

Biasing network BN is configured to receive a DC supply voltage V1 at an input node. This same node is RF shorted using a capacitor C3. This low RF impedance is transformed to an RF open at a frequency within the operational frequency band by a quarter-wavelength transformer 3 or lumped equivalent thereof.

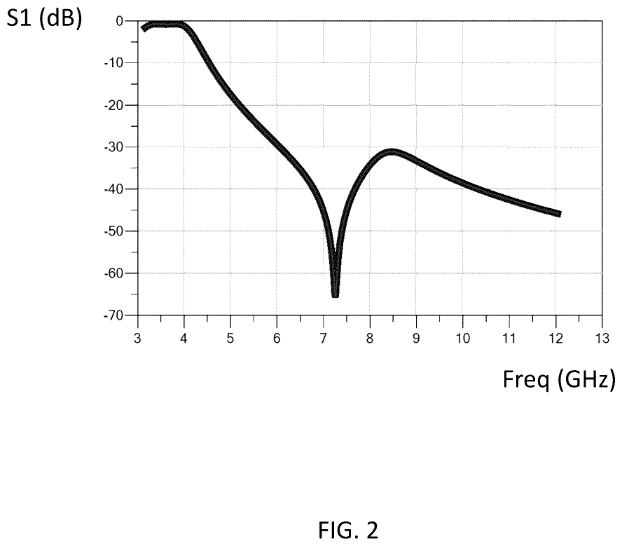

FIG. 2 illustrates the input reflection coefficient Si determined at the input terminal of transistor Q1 as shown in FIG. 1 as a function of frequency, wherein it is assumed that the input behavior of transistor Q1 is fully determined by Rg and Cgs. A sharp reduction in Si can be observed at 7.2 GHz, which corresponds to an RF short presented at twice the operational frequency f₂=2f₀. Furthermore, in this example f₀=f₁ so that at frequency f₀ both Cgs is compensated for, and an RF short is presented at the second harmonic frequency.

To allow broadband operation, it is possible that objectives A) and B) are met at different frequencies f. More specifically, f₁≠f₂. Furthermore, objectives A) and B) may (e.g., need) not be reached at frequency f₀.

In addition to the above, it is possible to connect multiple resonance networks to the input terminal. In such a case, a separate frequency can be designed for each resonance network at which an RF short is presented at the input terminal of Q1. For example, a first resonance network may be characterized by frequencies f₂₁ and f₁, whereas a second resonance network may be characterized by frequencies f₂₂ and f₁, wherein f₂₁ and f₂₂ correspond to frequency f₂ and can be determined using Equation 10. An RF short at the second harmonic is realized by each resonance network separately. For this reason, the frequency at which the n-th resonance network among N resonance networks may (e.g., will) present an RF short may (e.g., will) be referred to as 2×f₂ₙ. However, the resonance networks combined may (e.g., will) cancel the input susceptance of transistor Q1.

The amplifier may include (e.g., comprise) a substrate, and a semiconductor die on which the transistor is integrated. The transistor may include (e.g., comprise) a first bond assembly that is electrically connected to the input terminal of the transistor. The first inductor of each resonance network may at least partially be formed by one or more bondwires that are physically connected to the first bond assembly. The substrate can be in the form of a printed circuit board, multi-layer laminate, lead-frame, or the like.

The amplifier may further include (e.g., comprise) a further die on which at least the first capacitor of each resonance network is arranged, wherein a first terminal of the first capacitor is electrically connected to a second bond assembly that is arranged on the further die, wherein another end of the one or more bondwires is physically connected to the second bond assembly, and wherein a second terminal of the first capacitor is configured to be grounded during operation. The first capacitor can be a metal-insulator-metal capacitor integrated on the further die. Additionally, or alternatively, the further die can be a semiconductor die, such as a Silicon die. Such further die may be configured for only integrating passive components.

The second inductor can be integrated on the further die, wherein a first end of the second inductor is connected to the first terminal of the first capacitor. The second capacitor can be integrated on the further die, wherein a first terminal of the second capacitor is connected to a second end of the second inductor, and wherein a second terminal of the second capacitor is configured to be grounded during operation. The second capacitor can be a high-density capacitor, such as a deep trench capacitor.

The further die can be mounted on a die pad arranged on the substrate, wherein the die pad is configured to be electrically grounded during operation. The further die may have a conductive substrate and/or a substrate that is provided with vias. In this case, a second terminal of the first capacitor and/or a second terminal of the second capacitor may be configured to be grounded during operation through the conductive substrate or through the vias in the substrate.

The impedance matching network can at least be partially arranged on the further die. For example, the impedance matching network may include (e.g., comprise) a shunt capacitor arranged on the further die.

According to a second aspect, the present disclosure (e.g., invention) provides an amplifier system that includes (e.g., comprises) a first amplifier and a second amplifier, wherein both the first amplifier and the second amplifier comprise an amplifier as defined above. Furthermore, the output terminals of the transistors of the first and second amplifiers can be mutually shorted, and the input terminals of the transistors of the first and second amplifiers can be electrically connected to each other through a resistive connection. The resistive connection ensures that the transistors of the first and second amplifiers are symmetrically driven.

The transistor of the first amplifier and the transistor of the second amplifier can be arranged on the same semiconductor die. In this case, the transistor of the first amplifier may include (e.g., comprise) a first plurality of input fingers that is connected to the first bond assembly of the first amplifier, and the transistor of the second amplifier may include (e.g., comprise) a second plurality of input fingers that is connected to the first bond assembly of the second amplifier. Furthermore, the first bond assemblies of the first and second amplifiers are mutually electrically connected through the resistive connection.

In a further implementation (e.g., embodiment), the first amplifier and the second amplifier may use the same further die. In this case, the impedance matching network for the first amplifier may include (e.g., comprise) a first matching capacitor arranged on the further die and having a non-grounded terminal and a grounded terminal, and one or more bondwires extending between the non-grounded terminal of the first matching capacitor and the first bond assembly of the first amplifier. Similarly, the impedance matching network for the second amplifier may include (e.g., comprise) a second matching capacitor arranged on the further die and having a non-grounded terminal and a grounded terminal, and one or more bondwires extending between the non-grounded terminal of the second matching capacitor and the first bond assembly of the second amplifier. The first and second matching capacitors can be combined into a single matching capacitor arranged on the further die. This single matching capacitor can be arranged in between the first capacitors of the first and second amplifiers.

According to a third aspect, the present disclosure (e.g., invention) provides a Doherty amplifier that includes (e.g., comprises) a Doherty splitter configured for splitting a signal to be amplified into a main signal and a peak signal, a main amplifier configured to amplify the main signal, a peak amplifier configured to amplify the peak signal, and a Doherty combiner for combining the amplified main signal and the amplified peak signal. At least one of the main amplifier and peak amplifier includes (e.g., comprises) the amplifier or the amplifier system as defined above.

Next, the present disclosure (e.g., invention) will be described in more detail referring to the appended drawings, wherein identical reference signs will be used to refer to the same or identical components, and wherein:

FIG. 1 illustrates a general concept of the present disclosure (e.g., invention);

FIG. 2 illustrates electrical characteristics corresponding to FIG. 1;

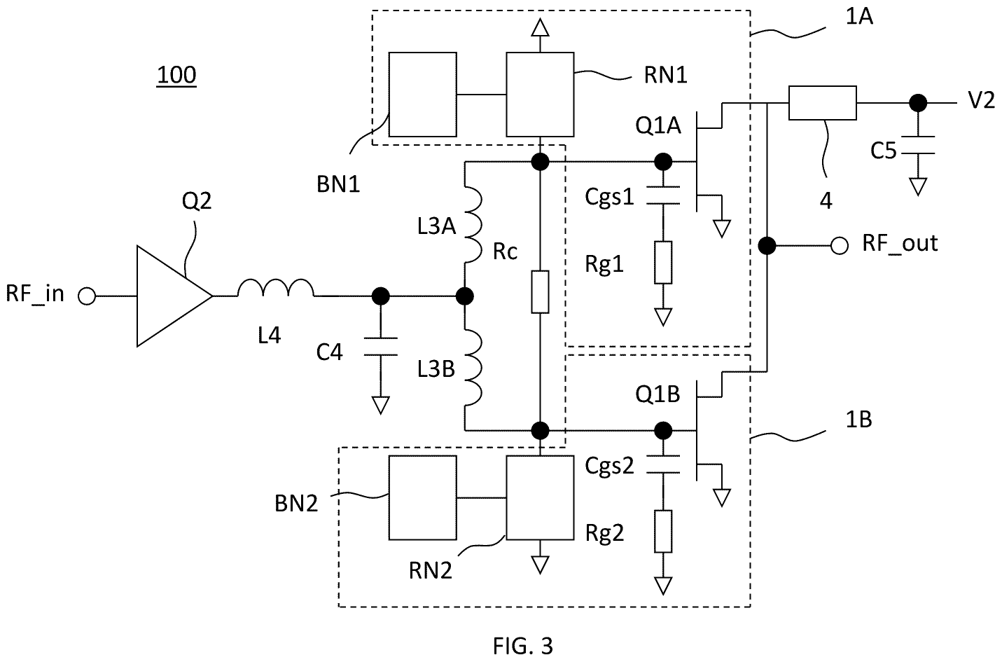

FIG. 3 illustrate an implementation (e.g., embodiment) of an amplifier system in accordance with the present disclosure (e.g., invention); and

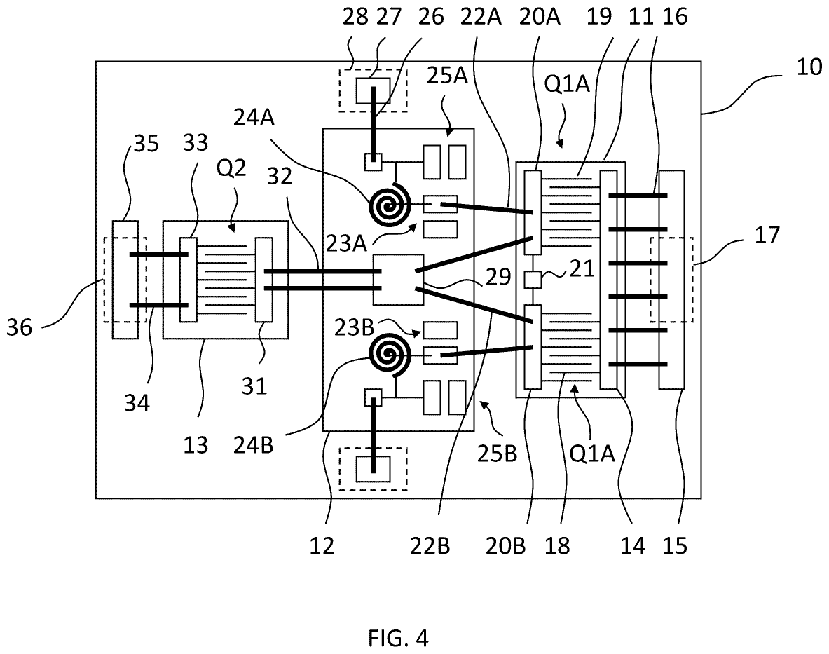

FIG. 4 illustrates a practical implementation of the implementation (e.g., embodiment) of FIG. 3.

In FIG. 3, an amplifier system 100 is shown that includes (e.g., comprises) an amplifier 1A and an amplifier 1, which are each configured as amplifier 1 shown in FIG. 1. FIG. 3 also illustrates a biasing network for biasing the drains of transistors Q1A, Q1B, which can be GaN-FETs. This biasing network includes (e.g., comprises) a shunt capacitor C5 of which the non-grounded terminal is connected to a voltage supply V2, and which is connected to the drains of Q1A, Q1B through a quarter-wavelength transformer 4 or lumped equivalent thereof. Furthermore, the gate-source capacitance and gate resistance for these transistors are indicated as Cgs1, Cgs2 and Rg1, Rg2, respectively. Resonance networks RN1, RN2, and biasing networks BN1, BN2, are only schematically illustrated.

Amplifier system 100 includes (e.g., comprises) a resistor Rc connected in between the gates of transistors Q1, Q2. This resistor prevents or limits having different gate voltages.

Amplifier system 100 further includes (e.g., comprises) a driving transistor Q2 and an interstage matching network formed by inductors L4, L3A, L3B and capacitor C4. Here, the interstage matching network and driving transistor Q2 can be thought of as two separate branches that have been partially merged, wherein each branch includes (e.g., comprises) a driving transistor and interstage matching network for a specific amplifier 1A, 1B.

FIG. 4 illustrates an implementation of amplifier system 100, wherein not every component in FIG. 3 is shown in FIG. 4.

Amplifier system 100 includes (e.g., comprises) a substrate 10 in the form of a multi-layer laminate on which a GaN semiconductor die 11, a first Silicon semiconductor die 12, and a second Silicon semiconductor die 13 are mounted.

GaN die 11 includes (e.g., comprises) transistors Q1A, Q1B. The drains of transistors Q1A, Q1B are connected to a drain bondbar 14, which is connected to a bondbar 15 on laminate 10 through one or more bondwires 16. Bondbar 15 is connected to a signal pad 17 arranged on a backside of laminate 10 through one or more vias (not shown).

Drain bondbar 14 is connected to a plurality of drain fingers 18. Transistors Q1A, Q1B each comprise a separate set of gate fingers 19, which are connected to gate bondbars 20A, 20B, respectively. A thin-film resistor 21 connects gate bondbars 20A, 20B.

Bondbars 20A, 20B are connected through one or more bondwires, 22A, 22B to a non-grounded terminal of metal-insulator-metal capacitor 23A, 23B integrated on first Silicon die 12. The other terminal of these capacitors is electrically grounded. For example, the semiconductor substrate of Silicon die 12 can be conductive or the substrate can be provided with vias. Here, it is noted that Silicon die 12 is mounted on a die pad (not shown) on laminate 10 that is electrically grounded during operation. For example, laminate 10 may include (e.g., comprise) ground vias or a coin that connect(s) a large ground pad (not shown) on the backside of laminate 10 to this die pad. It is noted that die pads are also used for dies 11, 13.

Each capacitor 23A, 23B is connected through an integrated inductor 24A, 24B to a non-grounded terminal of deep-trench capacitor 25A, 25B. The other terminal of capacitors 25A, 25B is grounded during operation.

At a node between inductor 24A, 24B and capacitor 25A, 25B, a biasing network is connected that includes (e.g., comprises) a bondwire 26 that connects to a bondpad 27 on laminate 10. Bondpad 27 is connected to a pad 28 on the backside of laminate 10.

Silicon die 12 further includes (e.g., comprises) a shunt capacitor 29, which is only schematically illustrated in FIG. 4. The non-grounded terminal of capacitor 29 is connected using bondwires 30A, 30B to gate bondbars 20A, 20B, respectively. This terminal is also connected to a drain bondbar 31 of a Silicon LDMOS transistor Q2 on Silicon die 13 through one or more bondwires 32. The gate bondbar 33 of Q2 is connected by one or more bondwires 34 to a bondbar 35 on laminate 10. Bondbar 35 is connected to a pad on the backside of laminate 10.

In amplifier system 100, bondwires 22A corresponds to first inductor L1 of FIG. 1, capacitor 23A to capacitor C1, inductor 24A to inductor L2, and capacitor 25A to capacitor C2.

In the implementation (e.g., embodiment), Silicon die 13 could be replaced by a further GaN die on which a GaN driver transistor is arranged. In addition, Silicon die 12 could be replaced by another die provided that the various capacitive and inductive components can be realized on such die.

In the above, the present disclosure (e.g., invention) has been explained using detailed implementations (e.g., embodiments) thereof. However, the present disclosure (e.g., invention) is not limited to these implementations (e.g., embodiments). Instead, various modifications are possible without departing from the scope of the present disclosure (e.g., invention), which is defined by the appended claims and their equivalents.

What is claimed is:

1. An amplifier configured to amplify signals within a given operational frequency band f₀±BW/2 that has a center frequency f₀ and a bandwidth BW, wherein the amplifier includes a transistor having an input terminal, and at least one resonance network arranged in between the input terminal and ground, wherein each resonance network comprises:
a first inductor arranged in between the input terminal and an intermediate node;
a first capacitor arranged in between the intermediate node and ground;
a series network arranged in between the intermediate node and ground that comprises a second inductor and a second capacitor;
wherein a susceptance presented by the at least one resonance network at the input terminal equals −B_{FET} at a frequency f₁ that lies in the operational frequency band, wherein B_{FET} is the input susceptance of the transistor at the frequency f₁;
wherein, for the n-th resonance network among the at least one resonance network:
the series network displays a series resonance at a frequency that is smaller than f₁;
an RF short is presented by the resonance network at the input terminal at a frequency 2×f₂ₙ, wherein the frequency f₂ₙ lies in the operational frequency band;
wherein n represents an integer between 1 and N with N being the total number of resonance networks.

2. The amplifier according to claim 1, wherein 0.8<f₂ₙ/f₁<1.2 or 0.9<f₂ₙ/f₁<1.1.

3. The amplifier according to claim 2, wherein each resonance network is designed such that at a respective frequency f₃ₙ, the series network is inductive and resonates with the first capacitor, wherein 2×f₂ₙ>f₃ₙ>f₁.

4. The amplifier according to claim 1, further comprising at least one biasing network for providing a biasing voltage to the input terminal of the transistor, wherein each respective biasing network is connected to a node in between the second inductor and the second capacitor of a respective resonance network.

5. The amplifier according to claim 1, further comprising a driver transistor of which an output is connected to the input terminal of the transistor through an impedance matching network.

6. The amplifier according to claim 1, comprising:
a substrate;
a semiconductor die on which the transistor is integrated, wherein the transistor comprises a first bond assembly that is electrically connected to the input terminal of the transistor;
wherein the first inductor of each resonance network is at least partially formed by one or more bondwires that are physically connected to the first bond assembly.

7. The amplifier according to claim 6, further comprising a further die on which at least the first capacitor of each resonance network is arranged, wherein a first terminal of the first capacitor is electrically connected to a second bond assembly that is arranged on the further die, wherein another end of the one or more bondwires is physically connected to the second bond assembly, and wherein a second terminal of the first capacitor is configured to be grounded during operation.

8. The amplifier according to claim 7, wherein the first capacitor is a metal-insulator-metal capacitor integrated on the further die.

9. The amplifier according to claim 7, wherein the further die is a semiconductor die, such as a Silicon die.

10. The amplifier according to claim 7, wherein the second inductor is integrated on the further die, wherein a first end of the second inductor is connected to the first terminal of the first capacitor.

11. The amplifier according to claim 10, wherein the second capacitor is integrated on the further die, wherein a first terminal of the second capacitor is connected to a second end of the second inductor, and wherein a second terminal of the second capacitor is configured to be grounded during operation.

12. The amplifier according to claim 11, wherein the second capacitor is a high-density capacitor, such as a deep trench capacitor.

13. The amplifier according to claim 7, wherein the further die is mounted on a die pad arranged on the substrate, wherein the die pad is configured to be electrically grounded during operation, wherein the further die has a conductive substrate or a substrate that is provided with vias, wherein a second terminal of the first capacitor or a second terminal of the second capacitor is configured to be grounded during operation through the conductive substrate or through the vias in the substrate.

14. The amplifier according to claim 7, further comprising a driver transistor of which an output is connected to the input terminal of the transistor through an impedance matching network, wherein the impedance matching network is at least partially arranged on the further die.

15. The amplifier according to claim 1, wherein the transistor is a Gallium Nitride-based field-effect transistor, GaN FET, and wherein the input terminal of the transistor is a gate of the GaN FET.

16. The amplifier according to claim 1 wherein f₀ lies in a range between 0.9 and 6.0 GHz, and wherein BW/f₀ lies in a range between 0.01 and 0.15.

17. An amplifier system comprising a first amplifier and a second amplifier, wherein both the first amplifier and the second amplifier comprise an amplifier configured to amplify signals within a given operational frequency band f₀±BW/2 that has a center frequency f₀ and a bandwidth, wherein the amplifier includes a transistor having an input terminal, and at least one resonance network arranged in between the input terminal and ground, wherein each resonance network comprises:
a first inductor arranged in between the input terminal and an intermediate node;
a first capacitor arranged in between the intermediate node and ground;
a series network arranged in between the intermediate node and ground that comprises a second inductor and a second capacitor;
wherein a susceptance presented by the at least one resonance network at the input terminal equals −B_{FET} at a frequency f₁ that lies in the operational frequency band, wherein B_{FET} is the input susceptance of the transistor at the frequency f₁;
wherein, for the n-th resonance network among the at least one resonance network:
the series network displays a series resonance at a frequency that is smaller than f₁;
an RF short is presented by the resonance network at the input terminal at a frequency 2×f₂ₙ, wherein the frequency f₂ₙ lies in the operational frequency band;
wherein n represents an integer between 1 and N with N being the total number of resonance networks;
wherein output terminals of the transistors of the first and second amplifiers are mutually shorted, and
wherein the input terminals of the transistors of the first and second amplifiers are electrically connected to each other through a resistive connection.

18. The amplifier system to claim 17, wherein the amplifier of the first amplifier and the amplifier of the second amplifier each comprise:
a substrate;
a semiconductor die on which the transistor is integrated, wherein the transistor comprises a first bond assembly that is electrically connected to the input terminal of the transistor;
wherein the first inductor of each resonance network is at least partially formed by one or more bondwires that are physically connected to the first bond assembly;
wherein the transistor of the first amplifier and the transistor of the second amplifier are arranged on the same semiconductor die, wherein the transistor of the first amplifier comprises a first plurality of input fingers that is connected to the first bond assembly of the first amplifier, wherein the transistor of the second amplifier comprises a second plurality of input fingers that is connected to the first bond assembly of the second amplifier, wherein the first bond assemblies of the first and second amplifiers are mutually electrically connected through the resistive connection.

19. The amplifier system to claim 18, wherein the amplifier of the first amplifier and the amplifier of the second amplifier each further comprise:
a driver transistor (Q2) of which an output is connected to the input terminal of the transistor through an impedance matching network (2);
a further die on which at least the first capacitor of each resonance network is arranged, wherein a first terminal of the first capacitor is electrically connected to a second bond assembly that is arranged on the further die, wherein another end of the one or more bondwires is physically connected to the second bond assembly, and wherein a second terminal of the first capacitor is configured to be grounded during operation;
wherein the first amplifier and the second amplifier use the same further die;
wherein the impedance matching network for the first amplifier comprises:
a first matching capacitor arranged on the further die having a non-grounded terminal and a grounded terminal;
one or more bondwires extending between the non-grounded terminal of the first matching capacitor and the first bond assembly of the first amplifier;
wherein the impedance matching network for the second amplifier comprises:
a second matching capacitor arranged on the further die having a non-grounded terminal and a grounded terminal;
one or more bondwires extending between the non-grounded terminal of the second matching capacitor and the first bond assembly of the second amplifier;
wherein the first and second matching capacitors are combined into a single matching capacitor, wherein the single matching capacitor is arranged in between the first capacitors of the first and second amplifiers.

20. A Doherty amplifier, comprising:
a Doherty splitter configured for splitting a signal to be amplified into a main signal and a peak signal;
a main amplifier configured to amplify the main signal;
a peak amplifier configured to amplify the peak signal; and
a Doherty combiner for combining the amplified main signal and the amplified peak signal;
wherein at least one of the main amplifier and peak amplifier comprise the amplifier configured to amplify signals within a given operational frequency band f₀±BW/2 that has a center frequency f₀ and a bandwidth, wherein the amplifier includes a transistor having an input terminal, and at least one resonance network arranged in between the input terminal and ground, wherein each resonance network comprises:
a first inductor arranged in between the input terminal and an intermediate node;
a first capacitor arranged in between the intermediate node and ground;
a series network arranged in between the intermediate node and ground that comprises a second inductor and a second capacitor;
wherein a susceptance presented by the at least one resonance network at the input terminal equals −B_{FET} at a frequency f₁ that lies in the operational frequency band, wherein B_{FET} is the input susceptance of the transistor at the frequency f₁;
wherein, for the n-th resonance network among the at least one resonance network:
the series network displays a series resonance at a frequency that is smaller than f₁;
an RF short is presented by the resonance network at the input terminal at a frequency 2×f₂ₙ, wherein the frequency f₂ₙ lies in the operational frequency band;
wherein n represents an integer between 1 and N with N being the total number of resonance networks.
